(19) United States
(12) Patent Application Publication
(10) Pub. No.: US 2026/0213671 A1
(43) Pub. Date: Jul. 23, 2026

(54) DRIP-PROOF COVER AND INVERTER APPARATUS

(71) Applicant: Mitsubishi Electric Corporation, Tokyo (JP)

(72) Inventors: Keita TONOIKE, Tokyo (JP); Kazuto KIKUCHI, Tokyo (JP); Yoshiki TAKAHARA, Tokyo (JP); Yasuo FUJII, Tokyo (JP); Masahiro SAITOU, Tokyo (JP); Hiroyuki KIYONAGA, Tokyo (JP)

(73) Assignee: Mitsubishi Electric Corporation, Tokyo (JP)

(21) Appl. No.: 19/139,427

(22) PCT Filed: May 12, 2023
(86) PCT No.: PCT/JP2023/017935

§ 371 Date: Jun. 16, 2025

(51) Int. Cl. H02M 7/00; H05K 5/00; H05K 5/02; H05K 5/03; H05K 5/06

(52) U.S. Cl. CPC H02M 7/003; H05K 5/0017; H05K 5/0213; H05K 5/0247; H05K 5/03; H05K 5/069

(57) ABSTRACT

A drip-proof cover protects an inverter unit including a heat sink on a back surface of an inverter main body. The drip-proof cover includes: a cover top surface portion that covers a top surface of the inverter unit, a first gap being provided between the cover top surface portion and the top surface of the inverter unit; cover side surface portions that cover side surfaces of the inverter unit, second gaps being provided between the cover side surface portions and the side surfaces of the inverter unit; and a cover front surface portion that covers a front surface of the inverter unit. A vent is formed in the cover top surface portion, the vent being located at a position corresponding to the heat sink in a state where the cover top surface portion covers the top surface of the inverter unit.

### FIELD

The present disclosure relates to a drip-proof cover of an inverter apparatus and the inverter apparatus, the inverter apparatus dissipating heat generated by a heating element by means of a heat sink provided on a back surface of a main body.

### BACKGROUND

An inverter unit is a device that converts and outputs a frequency and a current value of an input current. The inverter unit generates heat due to an internal power loss at the time of power conversion. The inverter unit includes a plurality of components such as semiconductor elements and electronic components. If the temperature of a component exceeds a heatproof temperature of the component at the time of power conversion, the component will be damaged. When the component is damaged, the power conversion function of the inverter unit is impaired. Therefore, it is necessary for the inverter unit to appropriately dissipate the generated heat to cool the inverter unit.

In the inverter unit, the density of air warmed by heat generated by a heat generating device decreases, and an upward air current is generated in a direction opposite to gravity. Therefore, an opening is formed in a top surface of a body case so as to discharge, to the outside of the body case, the air warmed by heat generated by the heat generating device. Thus, necessary heat dissipation performance is ensured in the inverter unit.

Meanwhile, the inverter unit is a general-purpose electronic device, and is used under various environments. For example, when the inverter unit is used in cooling and heating air conditioning equipment, the inverter unit may be used in an environment where water droplets are generated due to dew condensation or the like. In this case, the inverter unit needs to have drip-proof performance for normally operating even when receiving water droplets from vertically above. In a case where water droplets enter the inverter unit and adhere to a plurality of conductive portions, a short circuit occurs between the conductive portions, and an unexpected current flows through a component. This causes damage to the component.

In order to address such a problem, a drip-proof cover is put on the inverter unit so as to impart drip-proof performance to the inverter unit. However, when a drip-proof cover is put on an inverter unit including a heat sink on an outer surface, an upward air current generated inside the drip-proof cover due to heat dissipation from the heat sink is hindered by a top surface portion of the drip-proof cover. In this case, since ventilation efficiency is deteriorated inside the drip-proof cover, there is a possibility that heat dissipation from the heat sink may be deteriorated.

Patent Literature 1 discloses a cover for an electronic device, the cover having a side surface with an opening formed therein.

### CITATION LIST

### Patent Literature

Patent Literature 1: Japanese Patent Application Laid-open No. 2005-286086

### SUMMARY OF INVENTION

### Problem to Be Solved by the Invention

When the capacity of an inverter unit increases, a ventilation slit is often provided on a side surface of a body case of the inverter unit. However, in the case of the cover described in Patent Literature 1, there is a possibility that water droplets may enter the inside of the cover from the opening formed in the side surface of the cover, and may further enter the inverter unit from a slit provided in a casing of the inverter unit. Therefore, there is a problem that, in the body case of the inverter unit, a position where the slit is provided is limited to a position on a surface other than the side surface of the body case.

The present disclosure has been made in view of the above, and an object of the present disclosure is to obtain a drip-proof cover capable of imparting drip-proof performance to an inverter unit including a heat sink that dissipates heat of an inverter and preventing deterioration in heat dissipation from the heat sink.

### Means to Solve the Problem

In order to solve the above-described problems and achieve the object, a drip-proof cover according to the present disclosure is a drip-proof cover for protecting an inverter unit including a heat sink on a back surface of an inverter main body. The drip-proof cover includes: a cover top surface portion that covers a top surface of the inverter unit, a first gap being provided between the cover top surface portion and the top surface of the inverter unit; cover side surface portions that cover side surfaces of the inverter unit, second gaps being provided between the cover side surface portions and the side surfaces of the inverter unit; and a cover front surface portion that covers a front surface of the inverter unit. A vent is formed in the cover top surface portion, the vent being located at a position corresponding to the heat sink in a state where the cover top surface portion covers the top surface of the inverter unit.

### Effects of the Invention

The present disclosure has the effect of obtaining a drip-proof cover capable of imparting drip-proof performance to an inverter unit including a heat sink that dissipates heat of an inverter and preventing deterioration in heat dissipation from the heat sink.

### BRIEF DESCRIPTION OF DRAWINGS

FIG. 1 is a perspective view of an inverter apparatus according to a first embodiment as viewed from the front.

FIG. 2 is a perspective view of an inverter unit included in the inverter apparatus illustrated in FIG. 1 as viewed from the front.

FIG. 3 is a perspective view of the inverter unit included in the inverter apparatus illustrated in FIG. 1 as viewed from the rear.

FIG. 4 is a top view of the inverter unit included in the inverter apparatus illustrated in FIG. 1 as viewed from above.

FIG. 5 is a longitudinal sectional view of the inverter apparatus illustrated in FIG. 1, along a side surface of the inverter apparatus.

FIG. 6 is a first longitudinal sectional view of the inverter apparatus illustrated in FIG. 1 as viewed from a front side.

FIG. 7 is a second longitudinal sectional view of the inverter apparatus illustrated in FIG. 1 as viewed from the front side.

FIG. 8 is a perspective view of the inverter apparatus illustrated in FIG. 1 as viewed from the rear.

FIG. 9 is an enlarged cross-sectional view of an operation unit of the inverter apparatus illustrated in FIG. 1.

FIG. 10 is a longitudinal sectional view of the inverter apparatus illustrated in FIG. 1, which illustrates a state in which a drip-proof cover of the inverter apparatus is provided with an eaves portion.

FIG. 11 is a longitudinal sectional view of the inverter apparatus illustrated in FIG. 1, which illustrates a state in which a wall portion is provided on a cover top surface portion of the drip-proof cover of the inverter apparatus.

FIG. 12 is a plan view of the drip-proof cover of the inverter apparatus illustrated in FIG. 1 before sheet metal folding.

FIG. 13 is a front view of the drip-proof cover of the inverter apparatus illustrated in FIG. 12 after sheet metal folding.

FIG. 14 is a perspective view of the drip-proof cover according to the first embodiment, for describing a method for fixing the drip-proof cover.

### DESCRIPTION OF EMBODIMENTS

Hereinafter, a drip-proof cover and an inverter apparatus according to an embodiment will be described in detail with reference to the drawings.

### First Embodiment

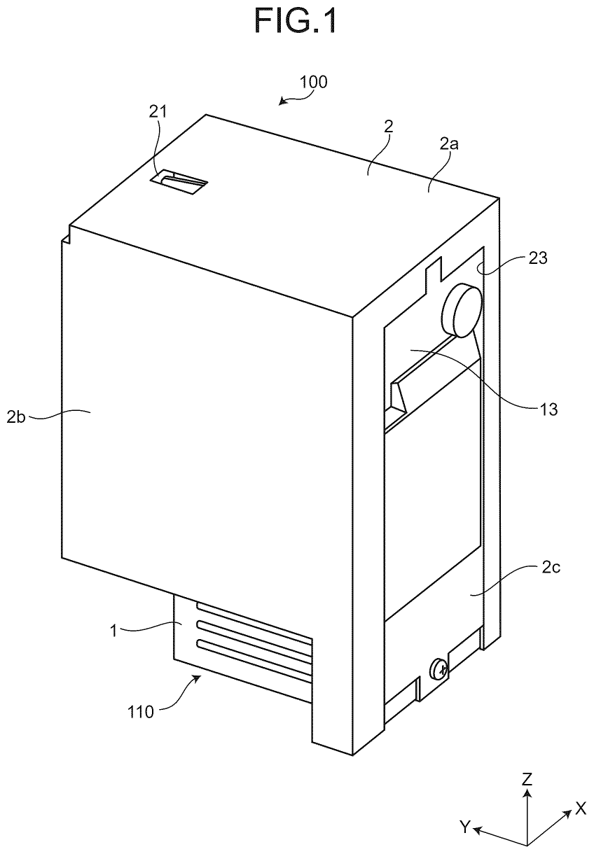

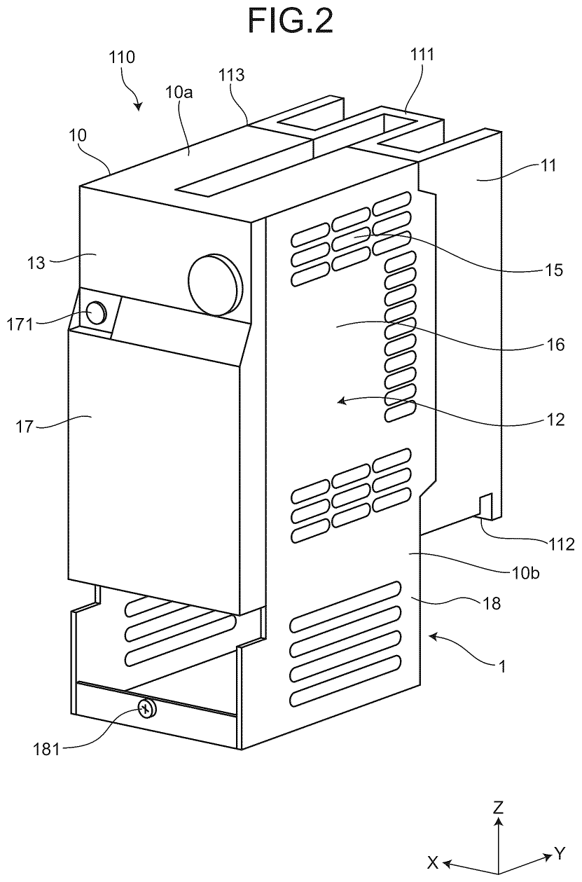

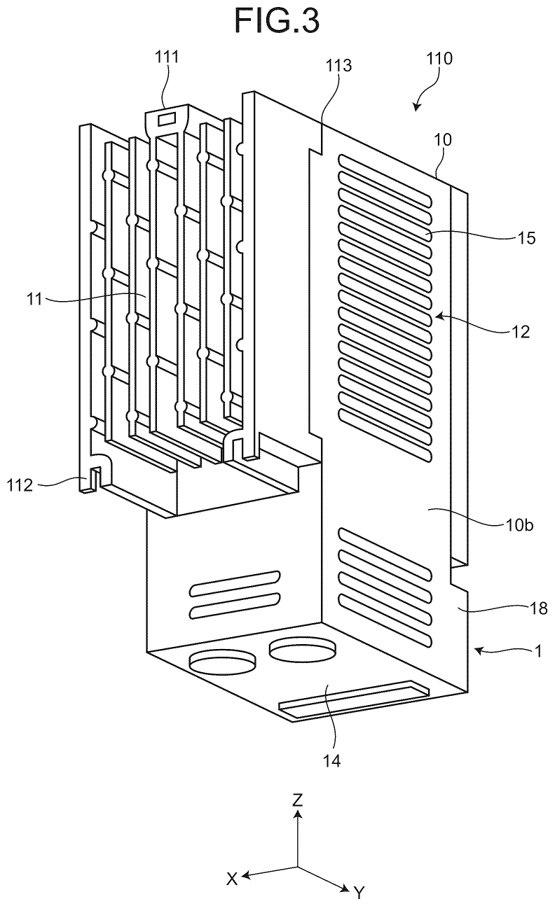

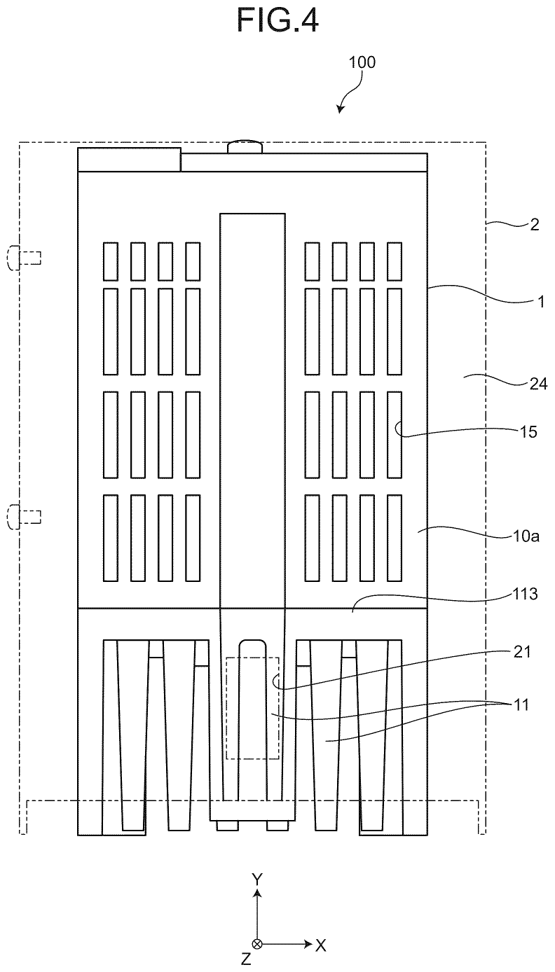

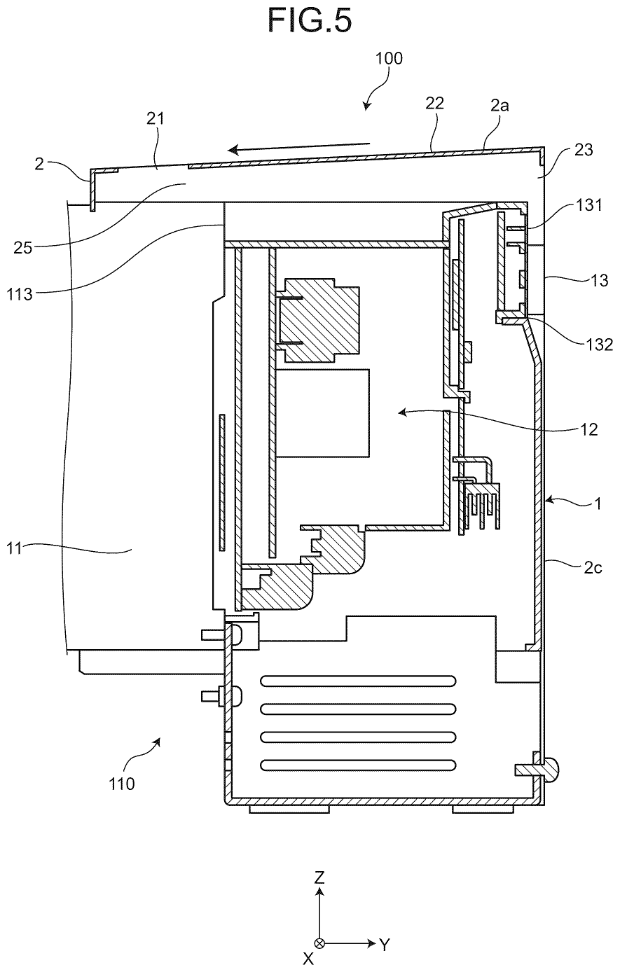

FIG. 1 is a perspective view of an inverter apparatus according to a first embodiment as viewed from the front. FIG. 2 is a perspective view of an inverter unit included in the inverter apparatus illustrated in FIG. 1 as viewed from the front. FIG. 3 is a perspective view of the inverter unit included in the inverter apparatus illustrated in FIG. 1 as viewed from the rear. FIG. 4 is a top view of the inverter unit included in the inverter apparatus illustrated in FIG. 1 as viewed from above. FIGS. 2 and 3 illustrate the inverter unit to which a drip-proof cover 2 has not been attached, in an inverter apparatus 100. In FIG. 4, a position where the drip-proof cover 2 is disposed is also indicated by a two-dot chain line. FIG. 5 is a longitudinal sectional view of the inverter apparatus illustrated in FIG. 1, along a side surface of the inverter apparatus.

The inverter apparatus 100 according to the first embodiment includes an inverter unit 110 and the drip-proof cover 2. The inverter unit 110 includes an inverter main body 1 and a heat sink 11. The inverter apparatus 100 is disposed such that a back side thereof faces a wall surface close to a control panel of equipment or a device to be controlled.

A width direction of the inverter apparatus 100 corresponds to a direction along a direction from the upper right to the lower left in FIG. 1, and corresponds to an X-axis direction in FIG. 1. A depth direction of the inverter apparatus 100 corresponds to a direction along a direction from the lower right to the upper left in FIG. 1, and corresponds to a Y-axis direction in FIG. 1. A height direction of the inverter apparatus 100 corresponds to a vertical direction in FIG. 1, and corresponds to a Z-axis direction in FIG. 1. The foreside and front side of the inverter apparatus 100 correspond to a direction toward the lower right in FIG. 1 along the depth direction of the inverter apparatus 100. The rear side and back side of the inverter apparatus 100 correspond to a direction toward the upper left in FIG. 1 along the depth direction of the inverter apparatus 100.

The inverter main body 1 is a device that converts and outputs a frequency and a current value of an input current, and has a rectangular parallelepiped outline. The inverter main body 1 includes an electronic component unit 12, an operation unit 13, and an external input/output unit 14 in a body case 10.

The electronic component unit 12 includes, in the body case 10, a semiconductor element which is a heat-generating component, electronic components such as a capacitor and a resistor, a plurality of substrates on which the electronic components are mounted, wires and connectors between the plurality of substrates, and the like, and forms an electric circuit. In the electronic component unit 12, a short-circuit fault will be caused by adhesion of water droplets to a plurality of wires and portions between the wires on the substrates, a plurality of terminals and portions between the terminals on the substrates, a plurality of electronic components and portions between the electronic components, and portions between any two or more of the wires, the terminals, and the electronic components. Therefore, the electronic component unit 12 needs to be protected from ingress of water droplets into the inverter main body 1. Therefore, the electronic component unit 12 is a target of drip-proof protection by the drip-proof cover 2.

Meanwhile, the electronic components are weak against heat, so that a plurality of openings 15 for heat release is provided in a side surface 10b of the body case 10. The openings 15 may be provided in a top surface 10a of the body case 10. Note that the size of each single opening 15 is reduced to such an extent that a finger or a tool cannot be inserted therein, so as to prevent any finger or tool from being accidentally inserted therein. The electronic component unit 12 is provided on the front side opposite to the wall surface across the heat sink 11 in the inverter main body 1.

The operation unit 13 is a user interface, and includes a button to be used by a user for configuring the settings for the inverter main body 1 and a device that displays various parameters in the inverter main body 1. When a water droplet enters the operation unit 13, a short circuit occurs in an internal electric component, and malfunction occurs. Therefore, the operation unit 13 is a target of drip-proof protection by the drip-proof cover 2.

The external input/output unit 14 is provided in a lower portion of the inverter main body 1, and performs electrical input/output from/to a device located outside the inverter main body 1. The external input/output unit 14 is connected to a wire to be used for input from a power supply device of the inverter main body 1 and a wire to be used for output to the device to be controlled by the inverter main body 1. When water adheres to a terminal connection portion in the external input/output unit 14, a short circuit occurs and malfunction occurs. However, the external input/output unit 14 can be protected from water droplets from above the inverter main body 1 by being provided at the lower portion of the inverter main body 1. Therefore, the external input/output unit 14 is not a target of drip-proof protection by the drip-proof cover 2.

The heat sink 11 has a plurality of fins. The heat sink 11 is fixed to the inverter main body 1 in a state of being in contact with the back surface of the inverter main body 1, and dissipates heat generated in the inverter main body 1 to the outside of the inverter unit 110. That is, the heat sink 11 dissipates heat generated by the electronic component unit 12 performing power conversion inside the inverter main body 1, to the outside of the inverter unit 110. The heat sink 11 includes an upper attachment portion 111 attached to the wall surface close to the control panel of the equipment or the device to be controlled, and a lower attachment portion 112 attached to the wall surface close to the control panel of the equipment or the device to be controlled. No problem is caused even when a water droplet drops onto the heat sink 11. An upper surface of the heat sink 11 is parallel to a horizontal plane in a state where the inverter unit 110 is installed.

The heat sink 11 is produced by a process such as die casting, shaving, or extrusion. The heat sink 11 is made of a material having relatively high thermal conductivity among materials, and conducts heat generated by a heat-generating component such as a semiconductor element of the electronic component unit 12 to release the heat into air outside the inverter unit 110. For example, various alloys including aluminum, magnesium, and alloys thereof can be used as the material having relatively high thermal conductivity among materials. There is no problem even if a water droplet adheres to the heat sink 11, except for a boundary portion 113 between the electronic component unit 12 and the heat sink 11. Therefore, the heat sink 11 is not a target of drip-proof protection by the drip-proof cover 2.

The drip-proof cover 2 is a cover that covers the top surface, side surfaces, and front surface of the inverter unit 110 to protect the inverter unit 110 and inhibit ingress of water droplets into the inverter main body 1. The drip-proof cover 2 includes a vent 21 only in a cover top surface portion 2a which is a top surface of the drip-proof cover 2 disposed above the heat sink 11. The drip-proof cover 2 discharges air inside the drip-proof cover 2 warmed by heat dissipated by the heat sink 11 and air inside the drip-proof cover 2 warmed by heat radiated from a surface of the electronic component unit 12, through the vent 21 of the cover top surface portion 2a of the drip-proof cover 2 to the outside of the drip-proof cover 2.

The vent 21 is formed at a position corresponding to the heat sink 11 on the horizontal plane, that is, at a position above the heat sink 11 in a state where the cover top surface portion 2a covers the top surface side of the inverter unit 110, that is, in a state where the cover top surface portion 2a covers the upper side of the inverter unit 110. Depending on the position of the vent 21 in the top surface of the drip-proof cover 2, there is a possibility that a water droplet having adhered to the drip-proof cover 2 and having entered the inside of the drip-proof cover 2 through the vent 21 may drop onto the electronic component unit 12 to enter the electronic component unit 12. Therefore, the vent 21 is provided in the cover top surface portion 2a of the drip-proof cover 2 such that the vent 21 is located at a position corresponding to the heat sink 11 on the horizontal plane in a state where the cover top surface portion 2a covers the top surface side of the inverter unit 110. As a result, it is possible to prevent a water droplet having adhered to the drip-proof cover 2 and having entered the inside of the drip-proof cover 2 through the vent 21 from dropping onto the electronic component unit 12. Furthermore, in the cover top surface portion 2a of the drip-proof cover 2, the vent 21 is formed at a position above a portion of the heat sink 11, the portion not having a shape that allows a water droplet having dropped onto the heat sink 11 to be transmitted to the electronic component unit 12.

The cover top surface portion 2a, which is the top surface of the drip-proof cover 2, is preferably an inclined surface inclined downward toward the back side of the inverter apparatus 100 as in an inclined portion 22 illustrated in FIG. 5. Note that the back side of the inverter apparatus 100 can be rephrased as the back side of the inverter unit 110.

Since the cover top surface portion 2a of the drip-proof cover 2 is the inclined portion 22 which is an inclined surface inclined downward toward the back side of the inverter apparatus 100, water droplets having adhered to the inclined portion 22 fall toward the wall surface behind the inverter apparatus 100. When the cover top surface portion 2a of the drip-proof cover 2 is not inclined and when the cover top surface portion 2a of the drip-proof cover 2 is inclined downward toward the front side of the inverter apparatus 100, water droplets having adhered to the cover top surface portion 2a of the drip-proof cover 2 may move along the back side of the cover top surface portion 2a of the drip-proof cover 2. In this case, since the water droplets drop after moving in a direction in which the cover top surface portion 2a of the drip-proof cover 2 is inclined downward, there is a possibility that the water droplets may drop onto the electronic component unit 12. Furthermore, even when there is no inclination in the cover top surface portion 2a of the drip-proof cover 2, there is a possibility that water droplets may move to a position above the electronic component unit 12 and drop onto the electronic component unit 12. Note that the back side of the inverter apparatus 100 can be rephrased as the back side of the inverter unit 110.

Note that examples of the case where a water droplet adheres to the back side of the cover top surface portion 2a of the drip-proof cover 2 include a case where a water droplet comes around to the back side of the cover top surface portion 2a of the drip-proof cover 2 through the vent 21 when the water droplet moves on the cover top Surface portion 2a of the drip-proof cover 2, and a case where a water droplet having passed through the vent 21 from above the cover top surface portion 2a of the drip-proof cover 2 is bounced back by the heat sink 11 and adheres to the back side of the cover top surface portion 2a of the drip-proof cover 2. Examples of the case where a water droplet moves on the cover top surface portion 2a of the drip-proof cover 2 include a case where a plurality of water droplets merge into a large water droplet on the cover top surface portion 2a of the drip-proof cover 2, and a case where a water droplet moves on the cover top surface portion 2a of the drip-proof cover 2 due to a factor of some kind, such as vibration or wind.

Also in a cover front surface portion 2c, which is the front surface of the drip-proof cover 2, when a water droplet having adhered to the cover top surface portion 2a of the drip-proof cover 2 or a cover side surface portion 2b, which is the side surface of the drip-proof cover 2, moves, the water droplet may come around to the back side of the drip-proof cover 2. Therefore, as illustrated in FIG. 1, the drip-proof cover 2 preferably covers the inverter unit 110 such that there is no gap at least in an edge portion where the cover top surface portion 2a of the drip-proof cover 2 and the cover side surface portion 2b of the drip-proof cover 2 are joined.

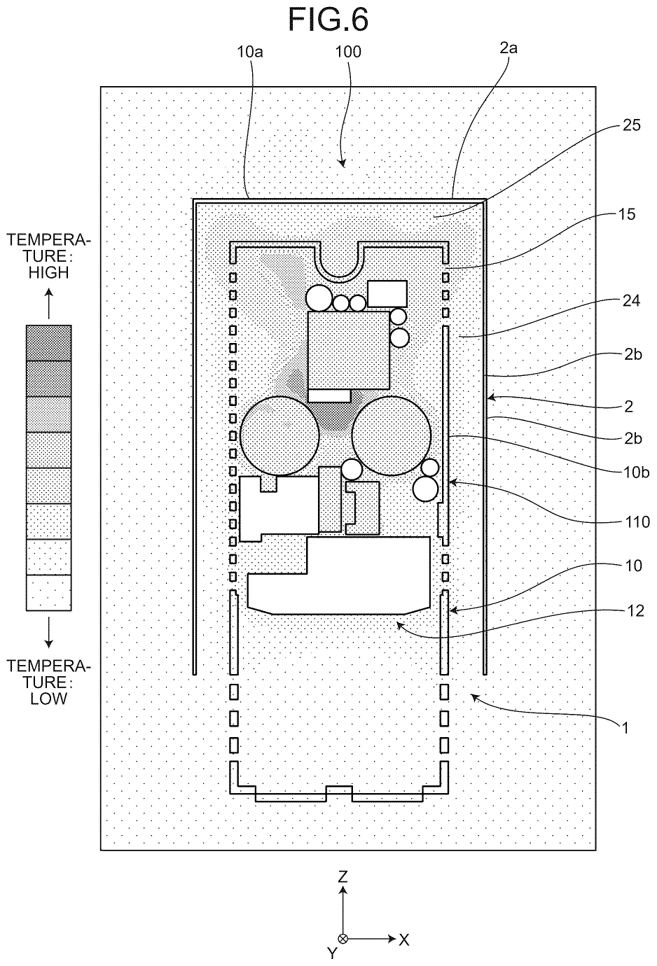

FIG. 6 is a first longitudinal sectional view of the inverter apparatus illustrated in FIG. 1 as viewed from the front side. FIG. 6 illustrates the distribution of temperature inside of the inverter apparatus 100 and around the inverter apparatus 100. In FIG. 6, circles and rectangles inside the inverter main body 1 indicate electronic components of the inverter main body 1. In FIG. 6, the level of air temperature is indicated by hatching. As can be seen from FIG. 6, air temperature is higher on the inner side of the inverter main body 1, and air temperature decreases toward the outside of the inverter main body 1.

As illustrated in FIG. 6, a first gap 24 is provided between the inverter unit 110 and the drip-proof cover 2 in the width direction in the inverter apparatus 100. That is, the first gap 24 is provided between the side surface 10b of the inverter main body 1 and the cover side surface portion 2b of the drip-proof cover 2 in the inverter apparatus 100. The side surface 10b of the inverter main body 1 and the cover side surface portion 2b of the drip-proof cover 2 are parallel to each other. Note that the first gap 24 also includes a space between the heat sink 11 and the cover side surface portion 2b of the drip-proof cover 2 in the width direction.

Since the first gap 24 exists between the side surface 10b of the inverter main body 1 and the cover side surface portion 2b of the drip-proof cover 2, the inverter apparatus 100 can obtain a heat dissipation effect by convecting air warmed inside the inverter main body 1 and to be discharged from the opening 15 of the side surface 10b of the inverter main body 1 to the outside of the inverter main body 1, toward the cover top surface portion 2a of the drip-proof cover 2

Note that, in order to obtain a heat dissipation effect by convection in the first gap 24, it is necessary to provide the first gap 24 of at least 1 mm or more in a horizontal direction, and it is preferable to provide the first gap 24 of about 10 mm so as to ensure a sufficient flow of air.

As illustrated in FIG. 6, a second gap 25 is provided between the top surface 10a of the inverter main body 1 and the cover top surface portion 2a of the drip-proof cover 2. The top surface 10a of the inverter main body 1 and the cover top surface portion 2a of the drip-proof cover 2 are parallel to each other. Since the second gap 25 exists between the top surface 10a of the inverter main body 1 and the cover top surface portion 2a of the drip-proof cover 2, the inverter apparatus 100 can obtain a heat dissipation effect by convecting air warmed inside the inverter main body 1 and to be discharged from the opening 15 of the side surface 10b of the inverter main body 1 to the outside of the inverter main body 1, and upper air warmed inside the inverter main body 1 and warmed by heat radiated from the top surface 10a of the inverter main body 1.

Note that, in order to obtain a heat dissipation effect by convection in the second gap 25, it is necessary to provide the second gap 25 of at least 1 mm or more in a height direction of the inverter apparatus 100, and it is preferable to provide the second gap 25 of about 10 mm so as to ensure a sufficient flow of air.

That is, by providing the gaps between the inverter main body 1 and the drip-proof cover 2, the inverter apparatus 100 can convect air between the inverter main body 1 and the drip-proof cover 2 to form the flow of air from the lower end portion of the drip-proof cover 2 to the outside of the drip-proof cover 2. Thus, the heat dissipation effect of the inverter main body 1 can be improved.

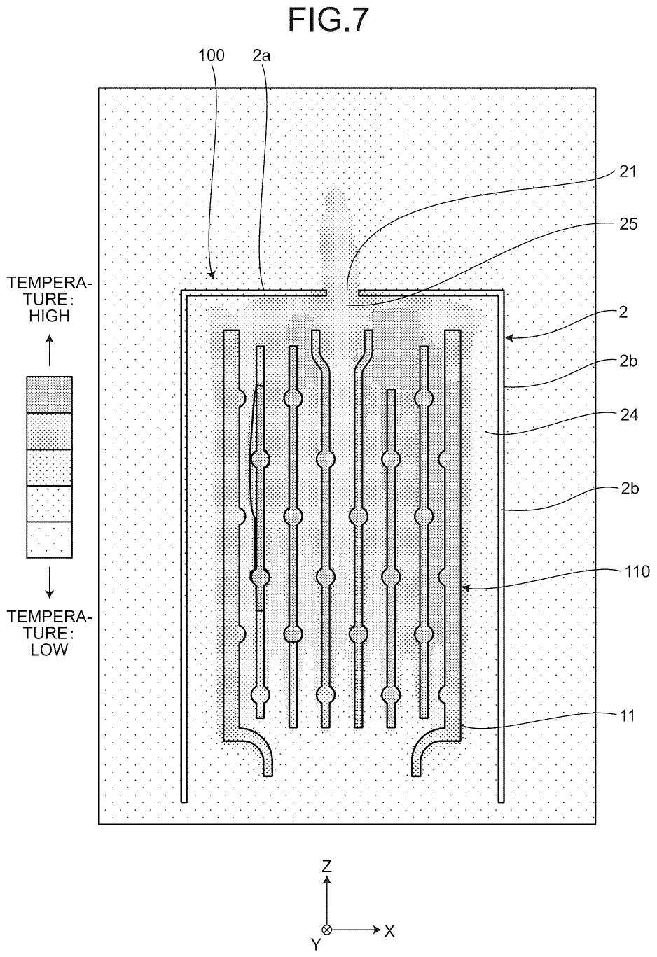

FIG. 7 is a second longitudinal sectional view of the inverter apparatus illustrated in FIG. 1 as viewed from the front side. FIG. 7 illustrates the distribution of temperature around the heat sink 11 in a cross section passing through the heat sink 11. In FIG. 7, the level of air temperature is indicated by hatching, as in FIG. 6. As can be seen from FIG. 7, air temperature is higher around the heat sink 11, and air temperature decreases toward the outside of the heat sink 11.

As illustrated in FIG. 7, the second gap 25 is provided between the inverter unit 110 and the drip-proof cover 2 in the height direction in the inverter apparatus 100. That is, the second gap 25 is provided between the heat sink 11 and the cover top surface portion 2a of the drip-proof cover 2 in the inverter apparatus 100. Note that the second gap 25 also includes a space between the inverter main body 1 and the cover top surface portion 2a of the drip-proof cover 2 in the height direction.

As can be seen from FIG. 7, air warmed inside the drip-proof cover 2 is accumulated in the second gap 25 in an upper part of the inside of the drip-proof cover 2, and the warmed air is discharged through the vent 21 of the drip-proof cover 2 to the outside of the drip-proof cover 2. As a result, it can be seen that the vent 21 of the drip-proof cover 2 has a heat dissipation effect.

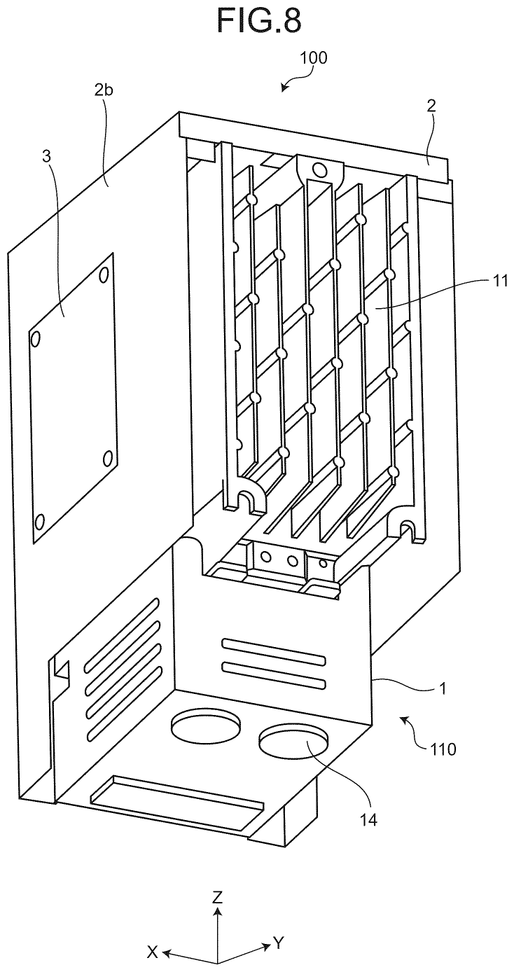

FIG. 8 is a perspective view of the inverter apparatus illustrated in FIG. 1 as viewed from the rear. As illustrated in FIG. 8, a part of the cover side surface portion 2b of the drip-proof cover 2 is formed as a transparent cover 3.

The transparent cover 3 makes the inside of the drip-proof cover 2 visible from the outside of the drip-proof cover 2. Since a part of the cover side surface portion 2b of the drip-proof cover 2 is formed as the transparent cover 3, it is possible to check, for example, information displayed on a device information display unit 16 provided in the inverter main body 1 illustrated in FIG. 2 without removing the drip-proof cover 2. Examples of the information to be displayed on the device information display unit 16 include information on the inverter unit 110 and information on the inverter main body 1, such as a name plate, a device configuration of the inverter unit 110, and an operation status of a device of the inverter main body 1.

In particular, a standard authentication mark is obliged to be placed on electronic devices such as inverters. Therefore, when the drip-proof cover hinders the standard authentication mark from being seen, it is necessary to show similar information on the drip-proof cover.

In the inverter apparatus 100, by making a part of the cover side surface portion 2b of the drip-proof cover 2 transparent, it is possible to check information displayed on the inverter main body 1 without removing the drip-proof cover 2. Accordingly, in the inverter apparatus 100, it is not necessary to additionally display information such as a standard authentication mark on the drip-proof cover 2.

A part of the cover side surface portion 2b of the drip-proof cover 2 is formed as the transparent cover 3 in the inverter apparatus 100. Meanwhile, for example, the inverter apparatus 100 may be configured such that, after a name plate portion in the inverter main body 1 is made waterproof, the transparent cover 3 is provided as an opening in the cover side surface portion 2b of the drip-proof cover 2 instead of being provided as a cover, and water is stopped between the drip-proof cover 2 and the inverter main body 1 with a gasket or a labyrinth structure. Also in this case, it is possible to check information displayed on the inverter main body 1 without removing the drip-proof cover 2, and to obtain an effect of not requiring additional notation of information on the drip-proof cover 2, as with the above.

Note that it is possible to obtain the above effect by partially forming, as a transparent cover, at least one of the cover top surface portion 2a, the cover side surface portions 2b, and the cover front surface portion 2c so that the inside of the drip-proof cover 2 can be seen from the outside of the drip-proof cover 2.

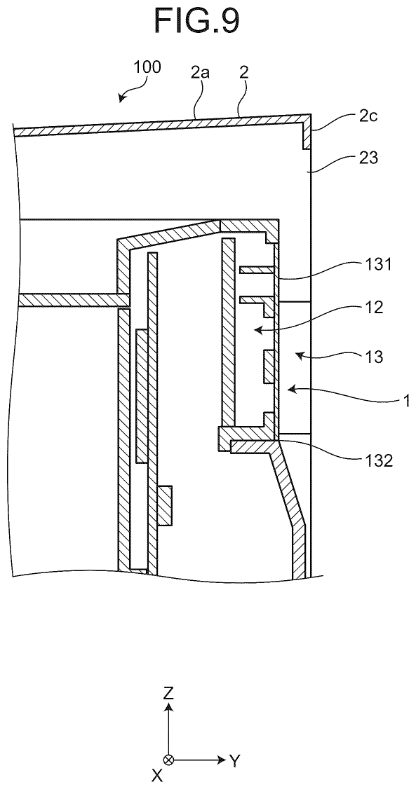

FIG. 9 is an enlarged cross-sectional view of the operation unit of the inverter apparatus illustrated in FIG. 1 FIG. 9 illustrates a state in which the operation unit 13 with a waterproof structure is exposed from an opening 23 formed in the cover front surface portion 2c. The operation unit 13 may have a structure in which no water droplet enters the electronic component unit 12 located inside the inverter main body 1, by means of a sheet button and a labyrinth structure in a button portion 131 and a joint 132 between components. As a result, the operation unit 13 is not a target of drip-proof protection by the drip-proof cover 2 in the inverter apparatus 100 As a result, the inverter apparatus 100 can achieve an effect of allowing the user to operate the operation unit 13 from the outside of the inverter apparatus 100 even in a state where the drip-proof cover 2 is attached.

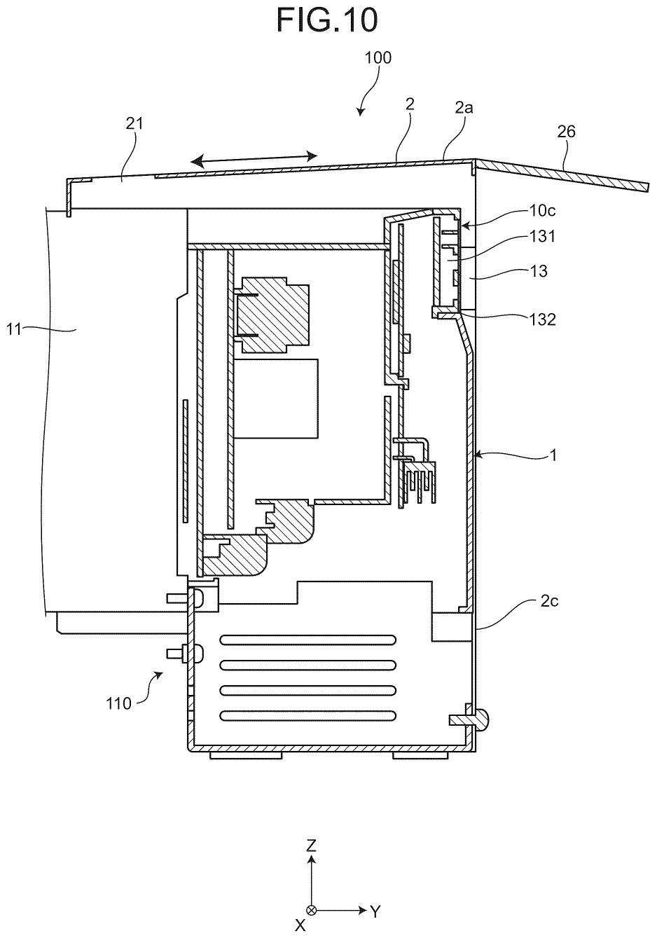

FIG. 10 is a longitudinal sectional view of the inverter apparatus illustrated in FIG. 1, which illustrates a state in which the drip-proof cover of the inverter apparatus is provided with an eaves portion. In FIG. 10, the drip-proof cover 2 covers the top surface of the inverter unit 110 in a state where an end portion of the cover top surface portion 2a of the drip-proof cover 2 extends forward in the depth direction relative to the placement position of the cover front surface portion 2c of the drip-proof cover 2. That is, in FIG. 10, an eaves portion 26 extending forward is provided at a front end portion of the cover top surface portion 2a of the drip-proof cover 2. It is possible to prevent water from entering the inverter main body 1 on the front side of the inverter main body 1, by extending the cover top surface portion 2a of the drip-proof cover 2 forward relative to the cover front surface portion 2c of the drip-proof cover 2 to provide the shape of the eaves portion 26 that covers a front surface 10c of the inverter main body 1. As a result, it is possible to eliminate the need for a waterproof structure such as a sheet button of the button portion 131 and a labyrinth structure of the joint 132 of the operation unit 13.

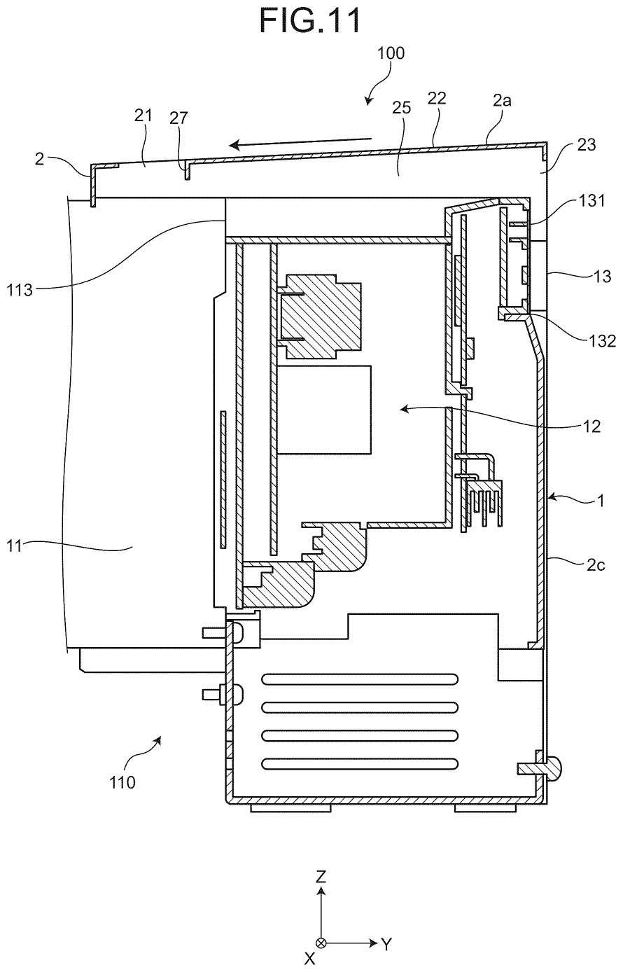

FIG. 11 is a longitudinal sectional view of the inverter apparatus illustrated in FIG. 1, which illustrates a state in which a wall portion is provided on the cover top surface portion of the drip-proof cover of the inverter apparatus. In FIG. 11, a wall portion 27 extending downward is provided at a portion of an open end of the vent 21 in the cover top surface portion 2a of the drip-proof cover 2, the portion of the open end being located on the front side.

The wall portion 27 is provided in such a way as to extend downward from the portion of the open end of the vent 21 in the cover top surface portion 2a of the drip-proof cover 2, the portion of the open end being located on the front side. The wall portion 27 guides water droplets downward, the water droplets moving on the cover top surface portion 2a of the drip-proof cover 2 from the front side toward the back side and dropping through the vent 21. That is, the wall portion 27 prevents water droplets from adhering to the back surface of the cover top surface portion 2a, the water droplets moving on the cover top surface portion 2a of the drip-proof cover 2 from the front side toward the back side and dropping through the vent 21.

By providing the wall portion 27, water droplets moving on the cover top surface portion 2a from the front side toward the back side and dropping through the vent 21 drop from the cover top surface portion 2a along the wall portion 27. Therefore, water droplets are prevented from adhering to the back side of the cover top surface portion 2a, the water droplets moving on the cover top surface portion 2a from the front side toward the back side and dropping through the vent 21. As a result, water droplets that move on the cover top surface portion 2a from the front side toward the back side and drop through the vent 21 are prevented from dropping onto the electronic component unit 12 along the back side of the cover top surface portion 2a. Thus, the water droplets are prevented from entering the electronic component unit 12.

In the inverter apparatus 100 illustrated in FIG. 11, the cover top surface portion 2a of the drip-proof cover 2 is formed as the inclined portion 22 which is an inclined surface inclined downward toward the back side of the inverter apparatus 100. In addition, the wall portion 27 is provided in such a way as to extend vertically downward from the portion of the open end of the vent 21 in the inclined portion 22, the portion of the open end being located on the front side. Then, water droplets that move on the inclined portion 22 from the front side toward the back side and drop through the vent 21 drop downward along the wall portion 27 from the inclined portion 22. Therefore, it is possible to prevent the water droplets that move on the inclined portion 22 from the front side toward the back side and drop through the vent 21 from adhering to the back side of the cover top surface portion 2a of the drip-proof cover 2. As a result, in the inverter apparatus 100 illustrated in FIG. 11, water droplets that move on the inclined portion 22 from the front side toward the back side and drop through the vent 21 are prevented from dropping onto the electronic component unit 12 along the back side of the inclined portion 22 and thus, the water droplets are prevented from entering the electronic component unit 12.

In addition, even when the cover top surface portion 2a of the drip-proof cover 2 is not inclined, it is possible to obtain the above-described effect by providing the wall portion 27.

Furthermore, the wall portion 27 just needs to extend downward from the portion of the open end of the vent 21 in the cover top surface portion 2a, the portion of the open end being located on the front side. For example, the wall portion 27 may be provided in such a way as to be inclined rearward while extending downward from the portion of the open end of the vent 21, the portion of the open end being located on the front side.

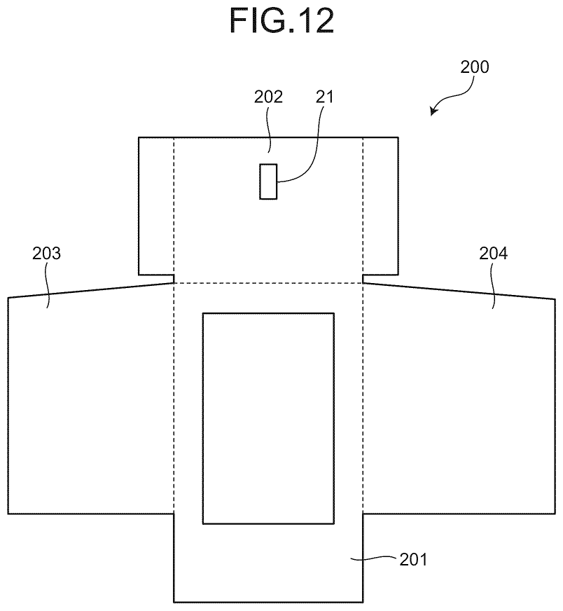

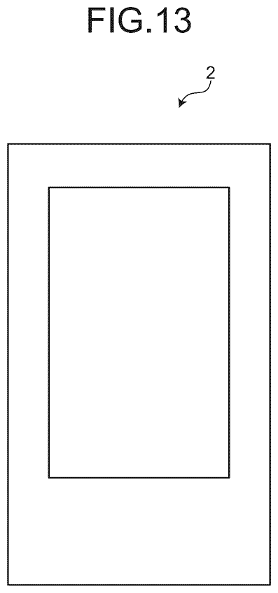

FIG. 12 is a plan view of the drip-proof cover of the inverter apparatus illustrated in FIG. 1 before sheet metal folding. FIG. 13 is a front view of the drip-proof cover of the inverter apparatus illustrated in FIG. 12 after sheet metal folding. FIG. 12 illustrates a raw sheet metal 200 of the drip-proof cover 2 before sheet metal folding. The raw sheet metal 200 is a single seamless sheet metal including a front sheet metal portion 201, a top sheet metal portion 202, and side sheet metal portions 203 and 204. The front sheet metal portion 201 is to be the cover front surface portion 2c of the drip-proof cover 2. The top sheet metal portion 202 is to be the cover top surface portion 2a of the drip-proof cover 2. The side sheet metal portions 203 and 204 are to be the cover side surface portions 2b of the drip-proof cover 2.

The drip-proof cover 2 may be a sheet-metal processing product that is an integrally formed part produced by sheet metal folding. Furthermore, the drip-proof cover 2 may be a resin molded product that is an integrally formed part produced by resin molding. It is possible to obtain a seamless cover and reduce a path through which water enters the inside of the drip-proof cover 2 when the drip-proof cover 2 covers the inverter apparatus 100, by forming the drip-proof cover 2 as a sheet-metal processing product which is an integrally formed part or a resin molded product which is an integrally formed part. Thus, the waterproof performance for the inverter main body 1 can be enhanced in the inverter apparatus 100.

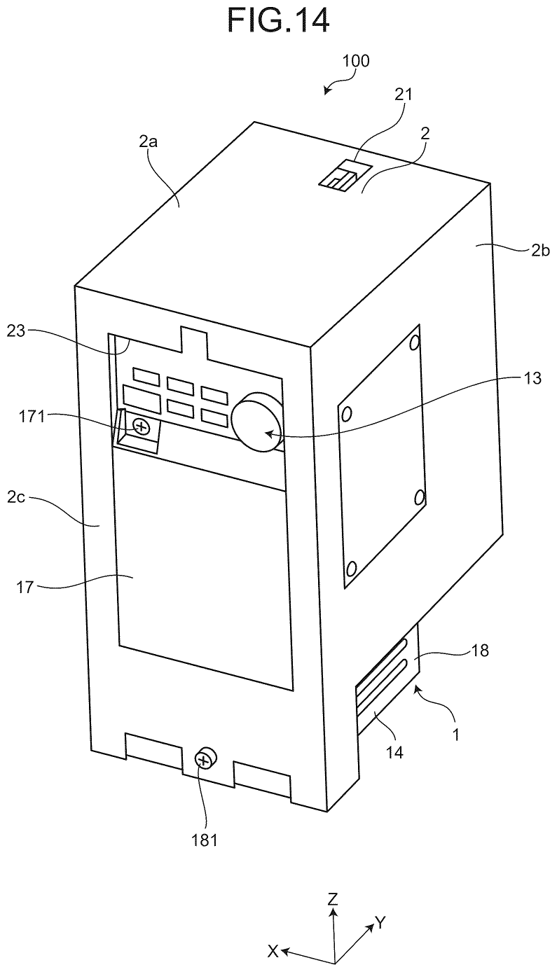

FIG. 14 is a perspective view of the drip-proof cover according to the first embodiment, for describing a method for fixing the drip-proof cover. In the drip-proof cover 2, at least one of the cover top surface portion 2a, the cover side surface portions 2b, and the cover front surface portion 2c can be fixed to the inverter unit 110 by sharing a screw fixation portion of the inverter unit 110.

In FIG. 14, the drip-proof cover 2 includes a cover-side screw fixation portion (not illustrated) formed at a position corresponding to a screw fixation portion 181 of a wiring cover 18 of the inverter main body 1. Thus, the drip-proof cover 2 is screwed to the inverter main body 1 by use of the screw fixation portion 181 of the wiring cover 18 and the cover-side screw fixation portion. That is, the drip-proof cover 2 includes a fixation portion that can be fixed to the inverter main body 1 by sharing the Screw fixation portion 181 of the wiring cover 18 of the inverter main body 1. Therefore, it is possible to attach the drip-proof cover 2 to the inverter main body 1 without removing the inverter main body 1 from an installation surface of the inverter apparatus 100. In addition, the drip-proof cover 2 may include a cover-side screw fixation portion formed at a position corresponding to a screw fixation portion 171 of a front cover 17 of the inverter main body 1.

Accordingly, at the time of installation of the inverter apparatus 100, the inverter main body 1 to which the drip-proof cover 2 has not been attached can be installed on the wall surface, and wiring work and setting work can be performed. As a result, workability of handling the external input/output unit 14 and the operation unit 13 is improved to obtain effects such as reduction of wiring errors, reduction of setting errors in various settings, and reduction of working hours.

As described above, in the inverter apparatus 100 according to the first embodiment, the drip-proof cover 2 can obtain good heat dissipation and drip-proof performance while maintaining the degree of freedom in designing the position of the vent 21 in the body case of the inverter unit 110.

Furthermore, in the inverter apparatus 100, air warmed by the heat sink 11 provided on the back surface of the inverter unit 110 generates an upward air current, and is discharged to the outside of the drip-proof cover 2 through the vent 21 of the cover top surface portion 2a of the drip-proof cover 2. As a result, in the inverter apparatus 100, accumulation of the warmed air inside the drip-proof cover 2 is prevented, and the flow speed of air flowing between the fins of the heat sink 11 is improved. It is thus possible to improve the heat dissipation performance of the inverter unit 110.

Moreover, the inverter apparatus 100 allows an opening to be freely provided in the side surface 10b and the top surface 10a of the inverter main body 1 by using the drip-proof cover 2. Then, in the inverter apparatus 100, heat of the inverter main body 1 is dissipated by convection of air discharged from the inside of the inverter main body 1 in the drip-proof cover 2. As a result, it is also possible to enhance heat dissipation performance regarding dissipation of heat of the inverter main body 1 from a portion other than the heat sink 11.

In addition, enhancement of the heat dissipation performance of the inverter main body 1 in the inverter apparatus 100 can achieve effects such as a fanless configuration, a reduction in the size of the inverter main body 1, an increase in the upper limit of use environment temperature, and an increase in the upper limit of the output of the inverter main body 1.

The configurations set forth in the above embodiment show examples, and it is possible to combine the configurations with another known technique or combine the techniques described in the embodiment with each other, and is also possible to partially omit or change the configurations without departing from the scope of the present disclosure.

### REFERENCE SIGNS LIST

1 inverter main body; 2 drip-proof cover; 2a cover top surface portion; 2b cover side surface portion; 2c cover front surface portion; 3 transparent cover; 10 body case; 10a top surface; 10b side surface; 11 heat sink; 12 electronic component unit; 13 operation unit; 14 external input/output unit; 15, 23 opening; 16 device information display unit; 18 wiring cover; 21 vent; 22 inclined portion; 24 first gap; 25 second gap; 26 eaves portion; 27 wall portion; 100 inverter apparatus; 110 inverter unit; 111 upper attachment portion; 112 lower attachment portion; 113 boundary portion; 131 button portion; 132 joint; 171, 181 screw fixation portion; 200 raw sheet metal; 201 front sheet metal portion; 202 top sheet metal portion; 203, 204 side sheet metal portion.

1. A drip-proof cover for protecting an inverter unit including a heat sink on a back surface of an inverter main body, the inverter main body including a body case accommodating a heat-generating component, the drip-proof cover being provided separately from the inverter unit and located outside of the inverter unit in such a way as to cover a top surface, side surfaces, and a front surface of the inverter unit, the drip-proof cover comprising:
cover side surface portions to cover the side surfaces of the inverter unit, first gaps being provided between the cover side surface portions and the side surfaces of the inverter unit;
a cover top surface portion to cover the top surface of the inverter unit, a second gap being provided between the cover top surface portion and the top surface of the inverter unit; and
a cover front surface portion to cover the front surface of the inverter unit, wherein
a vent is formed in the cover top surface portion, the vent being located at a position corresponding to the heat sink in a state where the cover top surface portion covers the top surface of the inverter unit.

2. The drip-proof cover according to claim 1, wherein
the first gap and the second gap are 1 mm or more.

3. The drip-proof cover according to claim 1, wherein
the cover top surface portion covers the top surface of the inverter unit in a state where the cover top surface portion is inclined downward toward a back surface of the inverter unit.

4. The drip-proof cover according to claim 1, wherein
at least one of the cover top surface portion, the cover side surface portions, and the cover front surface portion is partially formed as a transparent cover.

5. The drip-proof cover according to claim 1, wherein
the inverter main body includes an operation unit with a waterproof structure, the operation unit being located on a front of the inverter main body, and
an opening is formed in the cover front surface portion, the operation unit being exposed through the opening.

6. The drip-proof cover according to claim 1, wherein
the cover top surface portion covers the top surface of the inverter unit in a state where an end portion of the cover top surface portion extends forward relative to the cover front surface portion.

7. The drip-proof cover according to claim 1, wherein
the cover top surface portion, the cover side surface portions, and the cover front surface portion are integrally formed as a part made of a sheet-metal processing product or a resin molded product.

8. The drip-proof cover according to claim 1, wherein
the drip-proof cover has a fixation portion that allows at least one of the cover top surface portion, the cover side surface portions, and the cover front surface portion to be fixed to the inverter main body by sharing a screw fixation portion provided at the inverter unit.

9. The drip-proof cover according to claim 1, wherein
the cover top surface portion has a wall portion provided in such a way as to extend downward from a portion of an open end of the vent, the portion of the open end being located on a front side.

10. An inverter apparatus comprising:
the drip-proof cover according to claim 1; and
the inverter unit.

11. The drip-proof cover according to claim 2, wherein
the cover top surface portion has a wall portion provided in such a way as to extend downward from a portion of an open end of the vent, the portion of the open end being located on a front side.

12. The drip-proof cover according to claim 3, wherein
the cover top surface portion has a wall portion provided in such a way as to extend downward from a portion of an open end of the vent, the portion of the open end being located on a front side.

13. The drip-proof cover according to claim 4, wherein
the cover top surface portion has a wall portion provided in such a way as to extend downward from a portion of an open end of the vent, the portion of the open end being located on a front side.

14. The drip-proof cover according to claim 5, wherein
the cover top surface portion has a wall portion provided in such a way as to extend downward from a portion of an open end of the vent, the portion of the open end being located on a front side.

15. The drip-proof cover according to claim 6, wherein
the cover top surface portion has a wall portion provided in such a way as to extend downward from a portion of an open end of the vent, the portion of the open end being located on a front side.

16. The drip-proof cover according to claim 7, wherein
the cover top surface portion has a wall portion provided in such a way as to extend downward from a portion of an open end of the vent, the portion of the open end being located on a front side.

17. The drip-proof cover according to claim 8, wherein
the cover top surface portion has a wall portion provided in such a way as to extend downward from a portion of an open end of the vent, the portion of the open end being located on a front side.
